(19) United States
(12) Patent Application Publication
(10) Pub. No.: US 2016/0049279 A1
(43) Pub. Date: Feb. 18, 2016

(54) PLASMA DEVICE

(71) Applicants: Kee Won Suh, Suwon-si (KR); Allied Techfinders Co., Ltd., Suwon-si (KR)

(72) Inventor: Kee Won SUH, Suwon-Si (KR)

(73) Assignee: Allied Techfinders Co., Ltd., Suwon-Si (KR)

(21) Appl. No.: 14/825,894

(22) Filed: Aug. 13, 2015

(30) Foreign Application Priority Data
Aug. 14, 2014 (KR) 10-2014-0105914
Sep. 2, 2014 (KR) 10-2014-0116463
Jul. 20, 2015 (KR) 10-2015-0102462

(51) Int. Cl. H01J 37/32

(52) U.S. Cl. CPC H01J 37/32091; H01J 37/32651; H01J 37/3244

(57) ABSTRACT

A plasma device is proposed, the plasma device including a first member including a chuck unit accommodated with an antenna coil or a processed article so rotating as to generate a plasma inside a chamber, and a second member connected with a first harmonics power source, whereby a second harmonics power source that has pulsed a first harmonics power source is applied to the first member in response to the relative rotation of a first terminal of first member and a second terminal of second member.

### CROSS-REFERENCE TO RELATED APPLICATIONS

Pursuant to 35 U.S.C. §119 (a), this application claims the benefit of earlier filing dates and rights of priority to Korean Patent Applications No. 10-2014-0105914, filed on Aug. 14, 2014, and No.: 10-2014-0116463, filed on Sep. 2, 2014, and No.: 10-2015-0102462, filed on Jul. 20, 2015, the contents of which are hereby incorporated by reference in their entirety.

### BACKGROUND OF THE DISCLOSURE

1. Field

The teachings in accordance with the exemplary embodiments of this present disclosure generally relate to a plasma device configured to generate uniform plasma when processed articles such as substrates are processed.

2. Background

Plasma is used in surface treatment technology forming a fine pattern on a surface of a process article such as wafer or glass substrate. Various plasma sources generating the plasma have been developed in response to fine line spacing pitch or LCD size.

Representative methods of plasma sources may include a CCP (Capacitively Coupled Plasma) source of parallel planar surface plasma type, and an ICP (Inductively Coupled Plasma) source employing an antenna coil that couples RF (Radio Frequency) energy into a working gas in a vacuum chamber.

The former (CCP) has been primarily developed by TEL (Tokyo Electron) of Japan, and by LRC (Lam Resecircular arch) of USA, and the latter (ICP) has been largely developed by AMT (Applied Materials) and LRC of USA.

The ICP method may be advantageous in generating plasma at a low pressure and good fine circuit responsiveness due to excellent plasma density, while the ICP method suffers from disadvantages of decreased uniform plasma resultant from structural problems.

Although the CCP method may be advantageous in generating uniform plasma, the CCP method is disadvantageous because wafer or glass substrate, which is a processed article, is directly affected by electromagnetic field to inflict damage to fine pattern formation of the processed article. On top of that, the CCP source has a density relatively lower than that of ICP source to make the line spacing pitch narrower when processing the wafer to the disadvantage of pattern formation.

Furthermore, a high power may be applied to a broader region (7th generation and 8th generation) when processing a glass substrate, to make it difficult to transfer a uniform power to electrodes and to provide a greater damage to the processed article and to the device due to high power.

Although the Korean Patent Publication No.: 0324792 discloses a technology in which modulation by low frequency power is applied to high frequency power, the Publication fails to teach obtainment of plasma uniformity.

### SUMMARY OF THE DISCLOSURE

The present disclosure is to provide a plasma device configured to obtain a particle removal time by turning on/off an RF power source applied to an antenna coil by a mechanical intermittent contact structure. The present disclosure is to provide a plasma device configured to obtain a uniformity of plasma.

Technical problems to be solved by the present disclosure are not restricted to the above-mentioned description, and any other technical problems not mentioned so far will be clearly appreciated from the following description by the skilled in the art.

The present disclosure is to solve at least one or more of the above problems and/or disadvantages in whole or in part and to provide at least advantages described hereinafter. In order to achieve at least the above objects, in whole or in part, and in accordance with the purposes of the present disclosure, as embodied and broadly described, and in one general aspect of the present invention, there is provided a plasma device, the plasma device comprising:

a first member including a chuck unit accommodated with an antenna coil or a processed article so rotating as to generate a plasma inside a chamber; and

a second member connected with a first harmonics power source, wherein

the first member is provided with a terminal, and the second member is provided with a second terminal, and a second harmonics power source, which has pulsed the first harmonics power source in response to a relative rotation between the first and second terminals, is applied to the first member.

Preferably, but not necessarily, the first and second terminals may be alternately provided with a mutually and electrically connected conduction section and a mutually and electrically cut-off insulation section.

Preferably, but not necessarily, the first terminal may be arranged at a position tangent to an imaginary circumference, the second terminal may rotate along the imaginary circumference, and a length of the first terminal may be shorter than that of the imaginary circumference.

Preferably, but not necessarily, the first terminal may be provided in a plural number and each first terminal may be arranged by being spaced apart from the other first terminal.

Preferably, but not necessarily, an intermittent mechanical contact may be generated between the first and second terminals in response to the relative rotation between the first and second terminals, and the second harmonics power source may be applied to the first member, where the second harmonics power source intermittently turns on/off the first harmonics power source in response to the intermittent mechanical contact.

Preferably, but not necessarily, an intermittent mechanical contact may be generated between a frame ground terminal grounded to a frame and an antenna coil ground terminal grounded to an antenna coil, and the first member may be applied with the second harmonics power source that has pulsed the first harmonics power source as many as on/off frequency in response to the intermittent mechanical contact between the frame ground terminal and the antenna coil ground terminal.

Preferably, but not necessarily, at least one of the first terminal, the second terminal, the frame ground terminal and the antenna coil ground terminal may be at least one of a metal brush elastically contacted by a metal material, a conduction liquid, a slip module and a conduction bearing.

Preferably, but not necessarily, the antenna coil may be formed with a fan shape, and a circular arc portion of the antenna coil may be bent in a zigzag shape, and the antenna coil may rotate about a center of the circular arc as being a rotation shaft.

Preferably, but not necessarily, the antenna coil may be extended to a direction facing a periphery from the rotation shaft, a first section may be a section near to the rotation shaft compared with the second section, when the first section and the second section of radially same length are defined, and a length of a first portion in the antenna coil passing through the first section may be shorter than that of a second portion passing through the second section.

Preferably, but not necessarily, the antenna coil may rotate about the rotation shaft, the antenna coil may be bent in a zigzag shape and extended to a direction facing a periphery from the rotation shaft, and a width of the antenna coil may be gradually increased toward the periphery from the rotations shaft.

Preferably, but not necessarily, the antenna coil may rotate about the rotation shaft, and the antenna coil may be provided with a plurality of branch coils, each branch coil having a different rotation radius.

Preferably, but not necessarily, the plasma device may further comprise: a dielectric cover configured to tightly seal the chamber; and

a Faraday shield plate formed with a plate of metal material arranged between the dielectric cover and the antenna coil to be electrically grounded, wherein the antenna coil and the Faraday shield plate perform a relative movement when the plasma is generated.

Preferably, but not necessarily, the Faraday shield plate may include a slot extended to a direction perpendicular to an extension direction of the antenna coil or to a direction perpendicular to a current direction of the antenna coil, wherein the slot is opened to a direction perpendicular to the extension direction of the antenna coil or to a direction perpendicular to the current direction of the antenna coil.

Preferably, but not necessarily, the Faraday shield plate may be formed with a slot, wherein the slot includes a first slot facing a central area of the antenna coil, and a second slot facing a peripheral area of the antenna coil, and wherein the first slot is extended along a circumferential direction of the Faraday shield plate, and the second slot is extended along a radial direction of the Faraday shield plate.

Preferably, but not necessarily, the plasma device may further comprise an eddy current plate formed with a ferromagnetic substance or a paramagnetic substance and interposed between the antenna coil and the dielectric cover to be heated by the antenna coil or to heat the dielectric cover.

Preferably, but not necessarily, the eddy current plate may be arranged at a central hole centrally formed at the Faraday shield plate and un-grounded when the Faraday shield plate is grounded.

Preferably, but not necessarily, the plasma device may be provided with an RF window unit configured to support the dielectric cover and to tightly seal the chamber, wherein the RF window unit includes at least one of the Faraday shield plate, a cover plate formed with dielectric substance configured to cover the Faraday shield plate, an eddy current plate formed with a ferromagnetic substance or a paramagnetic substance, and a gas plate configured to eject gas into the chamber, and is formed therein with a gas supply path facing the gas plate.

Preferably, but not necessarily, the plasma device may be provided with a gas plate configured to eject gas into the chamber, and the gas plate may be protrusively formed with embossing patterns tightly attached to the dielectric cover, and a gas nozzle may be arranged among the embossing patterns configured to eject the gas into the chamber.

Preferably, but not necessarily, the plasma device may be provided with a gas plate, and when the gas plate is divided into a plurality of divisional areas, each divisional area may be divided by a dam pattern configured to protrude a portion of the gas plate.

Preferably, but not necessarily, the plasma device may be provided with restriction means configured to restrict generation of plasma in an empty space between the gas plate configured to supply the gas to the chamber and the dielectric cover, wherein the restriction means reduces a gap size between the gas plate and the dielectric cover, reduces a time in which the gas stays in the gas plate, increases mobility of the gas, or increases a partial pressure of the gas.

### Advantageous Effects of the Disclosure

The prior art has a problem in which plasma processing was continuously performed while pollutant materials such as particles separated from processed articles cover the processed articles due to continuous application of RF power source.

According to the present disclosure, plasma is intermittently applied to processed articles because the RF power source is intermittently applied, and the particles may be deviated from the processed articles by convection phenomenon inside the chamber while the plasma is not applied, whereby machining accuracy can be enhanced by obtaining a lead time (float) in which the pollutant materials such as particles can be removed during plasma processing.

The present disclosure has been realized in a mechanical intermittent contact structure instead of circuit nesting of two signals. The present disclosure can accomplish the plasma uniformity inside the chamber by generating plasma uniformly using a rotating antenna coil, and by providing a gas plate configured to supply gas in mutually different ratio to a central area and to an edge area, where a Faraday shield plate formed with a slot matching to the antenna coil can accomplish the plasma uniformity.

Furthermore, an eddy current plate configured to partially shield the electromagnetic wave projected into the chamber from the central area of the rotating antenna coil may be provided as a heat plate configured to evenly adjust the plasma inside the chamber.

### BRIEF DESCRIPTION OF DRAWINGS

FIG. 1 is a schematic view illustrating a plasma device according to an exemplary embodiment of the present disclosure.

FIG. 2 is a schematic view illustrating a processed state of processed article according to the present disclosure.

FIG. 3 is a schematic view illustrating a waveform of pulsed harmonics power source according to the present disclosure.

FIG. 4 is a schematic view illustrating a circuit configured to convert the harmonics power source into pulse form according to the present disclosure.

FIG. 5 is a schematic view illustrating a first terminal and a second terminal according to an exemplary embodiment of the present disclosure.

FIG. 6 is a schematic view illustrating a first terminal and a second terminal according to another exemplary embodiment of the present disclosure.

FIG. 7 is a schematic view illustrating a slip module according to an exemplary embodiment of the present disclosure.

FIG. 8 is a schematic view illustrating a slip module according to another exemplary embodiment of the present disclosure.

FIG. 9 is a schematic plan view illustrating a plasma device according to another exemplary embodiment of the present disclosure.

FIG. 10 is a perspective view illustrating an antenna coil according to an exemplary embodiment of the present disclosure.

FIG. 11 is a perspective view illustrating an antenna coil according to another exemplary embodiment of the present disclosure.

FIGS. 12 to 16 are schematic view illustrating an antenna coil according to still another exemplary embodiment of the present disclosure.

FIG. 17 is a schematic cross-sectional view illustrating a plasma device according to still another exemplary embodiment of the present disclosure.

FIG. 18 is an exploded perspective view illustrating an essential part at an upper surface of a plasma device according to the present disclosure.

FIG. 19 is a schematic plan view illustrating a Faraday shield plate according to the present disclosure.

FIG. 20 is a schematic plan view illustrating a gas plate according to the present disclosure.

### DETAILED DESCRIPTION OF THE DISCLOSURE

Hereinafter, exemplary embodiments of the present disclosure will be described in detail with reference to the accompanying drawings. In describing the present disclosure, certain layers, sizes, shapes, components or features may be exaggerated for clarity and convenience. Accordingly, the meaning of specific terms or words used in the specification and claims should not be limited to the literal or commonly employed sense, but should be construed or may be different in accordance with the intention of a user or an operator and customary usages. Therefore, the definition of the specific terms or words should be based on the contents across the specification.

A term of “pulsification” may be used for expression of pulse conversion (conversion into pulse form) in the exemplary embodiment of the present invention.

In the same context, a term of “pulsed” or “pulsified” may be used for expression of “pulse-converted” or “converted into pulse form” in the exemplary embodiment of the present invention.

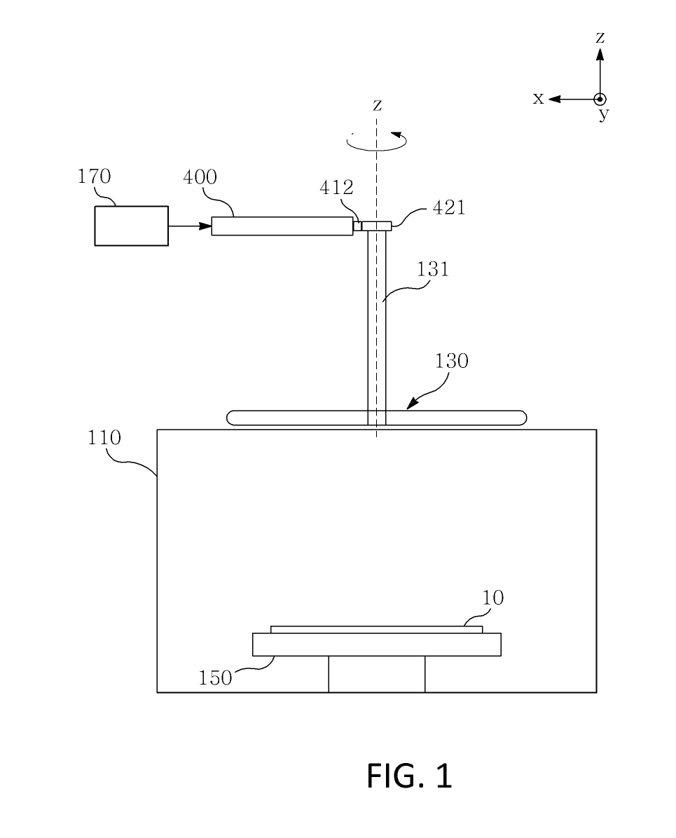

Referring to FIG. 1, a plasma device according to the present disclosure may include a first member configured to generate plasma and a second member (400) configured to apply a harmonics power source necessary for generating the plasma to the first member.

The first member may be an antenna coil (130) configured to generate the plasma, or a chuck coil (150). The second member (400) may apply the harmonics power source necessary for generating the plasma to the first member by generating the harmonics power source.

A terminal provided at the first member for electrical connection may be defined as a first terminal (421) and a terminal provided at the second member (400) may be defined as a second terminal (412). The first and second terminals (421, 412) may perform a relative rotation, where the second terminal (412) may apply a harmonics power source to the first terminal (421).

The first terminal (421) may rotate along with the first member while being fixed to the first member. Alternatively, the first member may rest and only the second terminal (421) rotates, while the first terminal (421) and the first member are electrically connected.

The second terminal (412) may rotate along with the second member (400) while being fixed to the second member (400). Alternatively, the second member may stand still and only the second terminal (421) rotates, while the second terminal (412) and the second member (400) are electrically connected. Furthermore, the relative rotation of the first and second terminals (421, 412) may be such that one of the first and second terminals (421, 412) maintains a stationary state while the other rotates. Alternatively, the first and second terminals (421, 412) may rotate at mutually different speed.

The relative rotation of the first and second terminals (421, 412) is to allow an electrical connection between the first and second terminals (421, 412) to be intermittently realized.

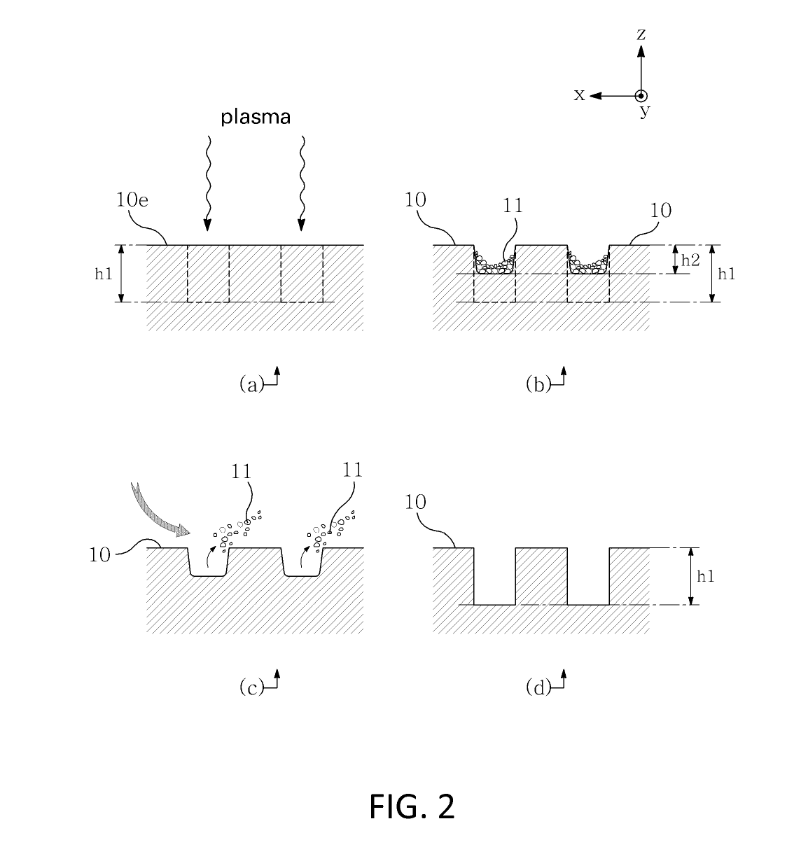

Referring to FIG. 2 (a), a plasma process may be performed on a surface of a substrate such as a processed article (10) to form a fine groove with a depth of h1. When the plasma generated on the first member strikes the processed article (10), a surface of the processed article (10) may be formed with a fine groove with a depth h2 lower than the groove h1 as shown in FIG. 2(b).

When the plasma process is continuously performed, a fine groove with a depth h1 must be formed but the reality is not as such. The reason is that impurities inside a chamber (110), or particles (11) separated from the processed article (10) by etching cover the fine groove. Even if the fine groove covered with particles (11) is struck, a relevant strike is received by the particles (11) to make it difficult to realize an additional etching. Thus, it is difficult to obtain a result (output) as shown in FIG. 2 (d) formed with an initially purported fine groove with the depth h1.

In order to form a fine groove with a depth h1, the impurities such as particles (11) covering the fine groove must be taken out from the fine groove as shown in FIG. 2 (c). This process may be a pumping process. A convection phenomenon may be used to perform the pumping process.

The first member may be arranged at an external side or at an inside of the chamber (110). The plasma may be generated by the first member inside the chamber (110) and the relevant plasma may move toward the processed article (10). At this time, imbalance in temperature may be generated inside the chamber (110). For example, a temperature at one side where the first member is situated in the chamber (110) may be higher than that of other sides. This difference in temperature may generate a convection phenomenon inside the chamber (110).

However, the particles (11) mentioned in FIG. 2 are difficult to be pumped out by the convection phenomenon, because the plasma moves towards the processed article (10) from the first member with a stronger force than the convection phenomenon. Therefore, in order to pump out the particles (11) in response to the convection phenomenon, the generation of plasma must be stopped. When the generation of plasma is stopped, the particles (11) that have covered the processed article (10) due to the convection phenomenon generated inside the chamber (110) can exit to outside of the processed article (10) as shown in FIG. 2(c).

When the plasma process is realized again to the processed article (10) while the particles (11) are removed by the pumping process, the fine groove with an initially designed depth of h1 may be formed on the processed article (10).

To wrap up, when no pumping process is applied, the plasma-processed processed article (10) may be transferred from FIG. 2(a) state to FIG. 2(b) state, and the processing may be finished. That is, a result (output) different from an initially designed value may be obtained.

Conversely, when the plasma process and the pumping process are alternately performed, FIG. 2(a) state, FIG. 2(b) state, FIG. 2(c) state and FIG. 2(d) state may be sequentially realized. That is, a result may be obtained that matches to the initially designed value. As discussed above, the harmonics power source applied to the first member can be pulsed (or pulse converted) in order for the plasma process and the pumping process can be alternately performed.

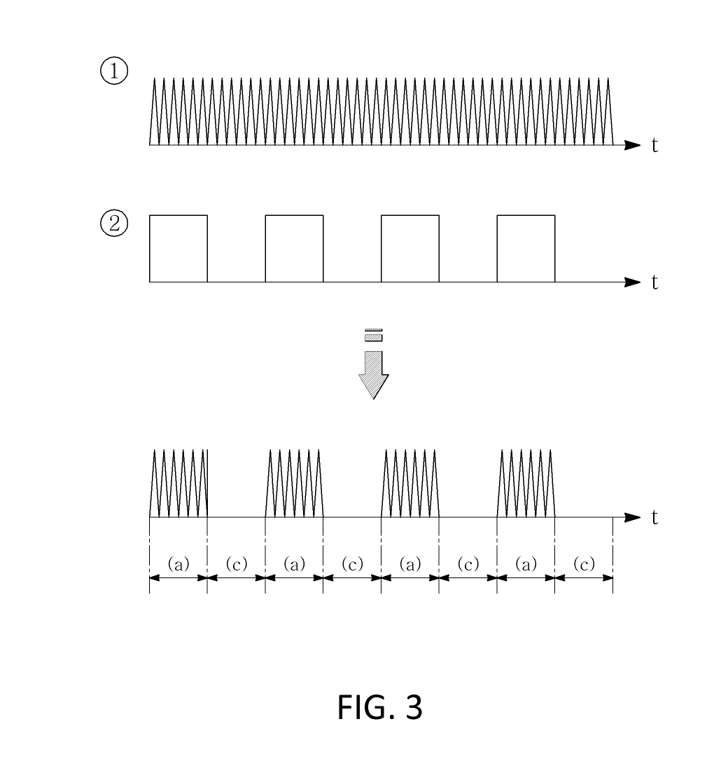

FIG. 3 is a schematic view illustrating a waveform of pulsed harmonics power source according to the present disclosure.

The harmonics power source \textcircled{1} generated by the first member may have a continuous waveform. When the harmonics power source \textcircled{1} is applied to the first member as it is, plasma process may be continuously realized. As a result therefrom, the pumping process is not realized to thereby obtain a processed result of FIG. 2(b) state.

The pulse conversion (conversion into pulse form) of the harmonics power source \textcircled{1} may be to process the harmonics power source \textcircled{1} in such a manner that the harmonics power source \textcircled{1} is outputted as it is at a particular section and the harmonics power source \textcircled{1} is not outputted at other particular sections.

For example, the harmonics power source \textcircled{1} may be pulse-converted by multiplying a pulse signal such as \textcircled{2} by the harmonics power source \textcircled{1}, by AND operation or by filtering. When the pulsed result is viewed, it can be noted that the harmonics power source \textcircled{1} is outputted as it is at a particular section (a) and the harmonics power source \textcircled{1} is not outputted at other particular sections (c).

According to the configuration thus discussed, plasma is applied to the processed article (10) at the particular section (a), and plasma is not applied to the processed article (10) at the particular section (c). As a result, the pumping process may be performed at the particular section (c). The method of converting the harmonics power source \textcircled{1} into pulse form may be diversified.

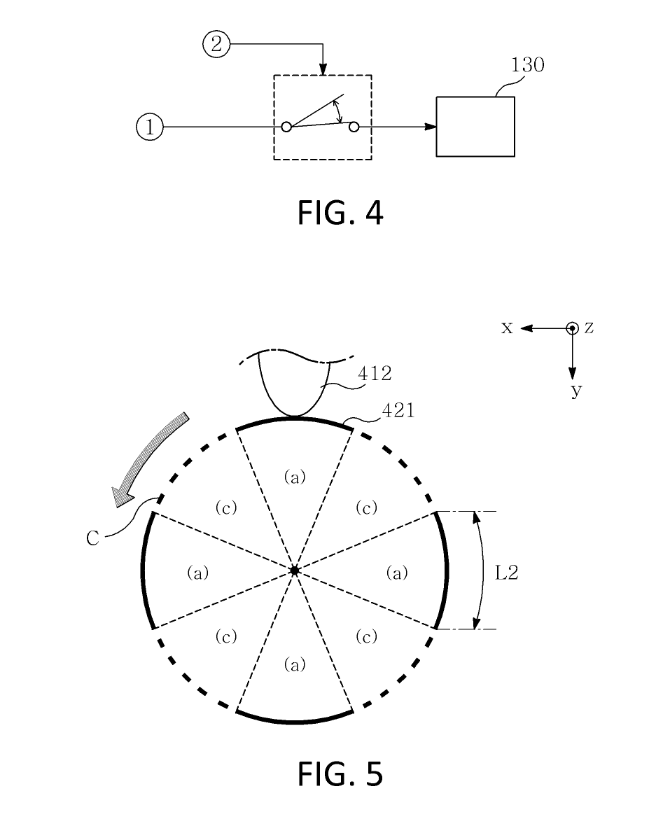

FIG. 4 is a schematic view illustrating a circuit configured to convert the harmonics power source into pulse form (to pulse the harmonics power source) according to the present disclosure.

A switching unit (indicated in square dotted lines) may be provided between the first member and the second member (400) to pulse the harmonics power source \textcircled{1}. The harmonics power source \textcircled{1} may be inputted to an input terminal of the switching unit, and a control terminal may be inputted with a pulse signal \textcircled{2}. The switching unit may output the harmonics power source \textcircled{1} as it is at a high level section of pulse signal and may block the harmonics power source \textcircled{1} at a low level section of pulse signal.

Meanwhile, when the switching unit is configured in a circuit, it is difficult to use for a long time and prone to malfunction. The relative rotation of first terminal (421) and the second terminal (412) in the plasma device according to the present disclosure may be to realize the switching unit in a mechanical manner.

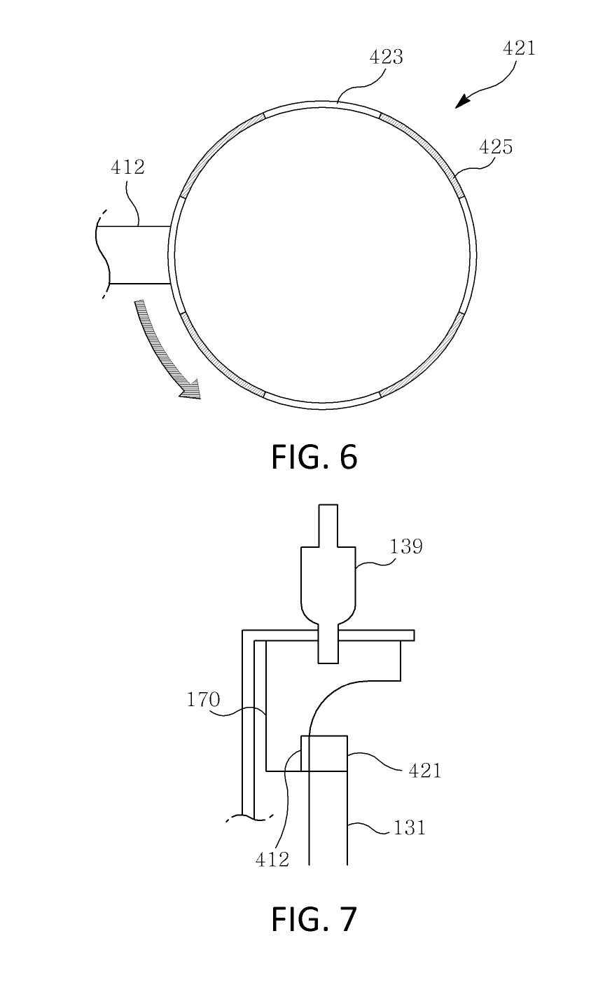

FIG. 5 is a schematic view illustrating a first terminal and a second terminal according to an exemplary embodiment of the present disclosure.

The first terminal (421) and the second terminal (412) may be alternately provided with a conduction section and an insulation section. The conduction section may be a section where the two terminals are electrically connected when the first terminal (421) and the second terminal (412) rotate relatively. The insulation section may be a section where the two terminals are electrically disconnected when the first terminal (421) and the second terminal (412) rotate relatively.

When the first terminal (421) and the second terminal (412) rotate relatively, at least one terminal may perform a rotation movement or a circle movement along an imaginary circle c. At this time, the conduction section and the insulation section may be formed on a circumference of the imaginary circle c.

For example, the first terminal (421) in FIG. 5 may be arranged a position tangent to the imaginary circumference c. Furthermore, the second terminal (412) may rotate along the imaginary circumference c. Under this state, a length L2 of the first terminal (421) may be shorter than a length L1 of the imaginary circumference c. Furthermore, the first terminal (421) may be provided in a plural number, and each first terminal (421) may be spaced apart at a predetermined distance.

According to the configuration thus discussed above, (a) section arranged with the first terminal (421) on the circumference c, and (c) section not arranged with the first terminal (421) may be discernible. At this time, the (a) section may be a conduction section and the (b) section may be an insulation section.

When the second terminal (412) rotates along the circumference c, the second terminal (412) may be brought into contact with the first terminal (421) when passing the (a) section. Furthermore, the second terminal (412) may be distanced from the first terminal (421) when passing the (b) section.

Thus, the harmonics power source \textcircled{1} may be outputted from the (a) section and the pulsification where the harmonics power source \textcircled{1} is not outputted may be realized at the (b) section. That is, the electrical connection between the first terminal (421) and the second terminal (412) is intermittently realized by mechanical contact to allow pulsing the harmonics power source.

The insulation section may be formed by not arranging the first terminal (421) on the imaginary circumference c. When the first terminal (421) is arranged by being spaced apart, the second terminal (412) may pass the first terminal (421), or pass a distanced-apart space between the first terminals (421). However, the second terminal (412) may be hitched by a lateral surface of the first terminal (421) when the second terminal (412) passes the distanced-apart space to contact the first terminal (421). As a result, as the lateral surface of the first terminal (421) functions as a stopper, the relative rotation of the first and second terminals may be restricted.

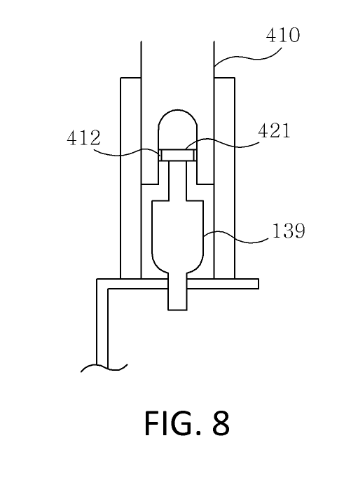

FIG. 6 is a schematic view illustrating a first terminal (421) and a second terminal (412) according to another exemplary embodiment of the present disclosure.

In order to solve the restriction of relative rotation caused by interference of the first terminal (421) and the second terminal (412), the first terminal (421) may include a circle (circular) terminal formed along the imaginary circumference c. To be more specific, a peripheral surface of the circle terminal may be provided along the imaginary circumference c.

The second terminal (412) may rotate along the imaginary circumference c. As a result, the second terminal (412) may continuously rotate in a state of being contacted with the peripheral surface of the circle terminal. At this time, the peripheral surface of the circle terminal may be alternately provided with an electric conductor (423) and an insulator (425), the configuration of which may generate the same effect of FIG. 5.

That is, the harmonics power source may be applied to the circle terminal corresponding to the first terminal (421) when the second terminal (412) passes a section provided with the conductor (423) on the circle terminal, whereby the first member provided with the first terminal (421) is generated with plasma and the processed article (10) may be plasma-processed.

If the second terminal (412) passes a section on the circle terminal provided with the insulator (425), the harmonics power source provided to the first terminal (421) may be blocked, whereby the first member is not generated with plasma and the pollutant material on the processed article may be pumped during this time.

According to relatively rotating first terminal (421) and second terminal (412), the second terminal (412) may alternately pass the conductor (423) and the insulator (425), whereby the harmonics power source pulsed as in FIG. 3 may be applied to the first member.

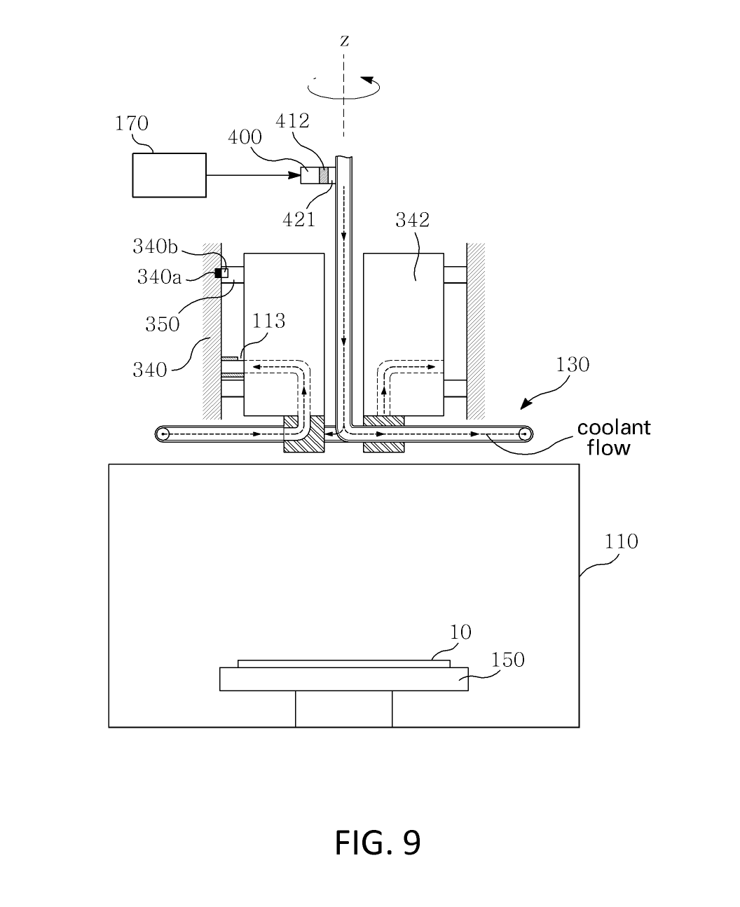

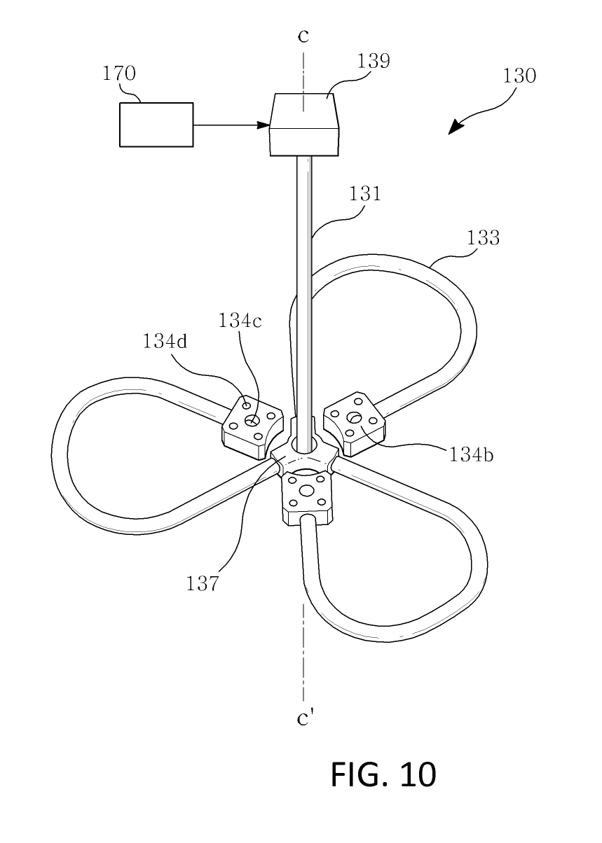

FIG. 7 is a schematic view illustrating a slip module according to an exemplary embodiment of the present disclosure, and FIG. 8 is a schematic view illustrating a slip module according to another exemplary embodiment of the present disclosure.

Referring to FIGS. 7 and 8, a slip module may be provided. The slip module may be interposed in order to electrically connect the relatively rotating first member and second member (400). The first terminal (421) provided on the slip module may be connected to the first member and the second terminal may be connected to the second member (400). The slip module may be provided with a harmonics power source connection unit (410), a slip ring (139) and a power source unit (170). The harmonics power source connection unit (410) may be connected to the second member (400). The power source unit (170) may be connected to the second member (400).

The slip ring (139) may be interposed between the harmonics power source connection unit (410) and the power source unit (170). To be more specific, one distal end of the slip ring (139) may be rotatatively inserted into the harmonics power source connection unit (410) and the other end may be rotatatively inserted into the power source unit (170).

According to the slip module thus configured, the harmonics power source connection unit (410) and the power source unit (170) may be electrically connected by the slip ring (139), even if the harmonics power source connection unit (410) and the power source unit (170) relatively rotate. The first terminal (421) and second terminal (412) thus explained may be provided at various positions on the slip module.

The first terminal (421) may be provided at a distal end of a central coil (131) contacting the power source unit (170) on the first member. In response thereto, the second terminal (412) may be provided with the power source unit (170).

The harmonics power source having passed the harmonics power source connection unit (410) and the slip ring (139) may be applied to the power source unit (170). The harmonics power source thus applied may be applied again to the distal end of the central coil (131). At this time, the harmonics power source can be pulsed in response to the mechanical intermittent contact when the first terminal (421) and second terminal (412) are configured to rotate relatively.

FIG. 8 is a schematic view illustrating another slip module provided with the first terminal (421) and second terminal (412).

The first terminal (421) may be provided at the slip ring (139). In response thereto, the second terminal (412) may be provided at the harmonics power source connection unit (410) or the power source unit (170), the configuration of which may also pulse the harmonics power source. In response to the configuration where the first terminal (421) and the second terminal (412) are relatively rotated, the first member and the second member (400) can mutually and relatively rotate.

The RF power source introduced into the second terminal (412) through an impedance matcher in a harmonics power source unit (RF power source) corresponding to the second member (400) may be provided to two or more parallel-connected antenna coils through the first terminal (421). At this time, the antenna coil may be an element comprising the plasma source to generate plasma while performing a circular movement by being rotated at a rotating speed of several RPMs to several hundred RPMs.

The second member (400) may be electrically connected to the rotating antenna through the slip ring (139) via the harmonics power source connection unit (410) formed with an impedance matcher, for example.

Now, various exemplary embodiments will be described with reference to FIGS. 1 to 9, in which a second harmonics power source that has pulsed the first harmonics power source is applied to the first member such as the antenna coil (130).

The first harmonics power source is a harmonics RF power source having a predetermined frequency in order to generate plasma as illustrated in FIG. 3 \textcircled{1}. The first harmonics power source has several hundred KHz˜several hundred MHz frequency, and may be applied to the second terminal (412) through the second member (400) by being generated from the power source (170).

The first member may be an antenna coil or a chuck unit (150), and the first member may be applied with a second harmonics power source. The second harmonics power source is a power source that has pulsed the first harmonics power source having several hundred KHz˜several hundred MHz frequency, as illustrated in FIG. 3, and a pulsed harmonics power source that has turned on and off the first harmonics power source of FIG. 3 \textcircled{1}, using a frequency of FIG. 3 \textcircled{2}.

The frequency of FIG. 3 \textcircled{2} is defined as an on/off frequency. The on/off frequency of FIG. 3 \textcircled{2} is proportionate to the number of rotation of the antenna coil (130), and proportionate to the number of insulation sections between the first and second terminals for each unit rotation of the antenna coil (130). That is, the on/off frequency is a frequency in which the number of insulation sections between the first and second terminals for each unit rotation of the antenna coil (130) is multiplied by the rotation speed of the antenna coil (130). At this time, the number of insulation sections is 4 in the exemplary embodiment of FIG. 5, and is the number of switching between the first and second terminals (421, 412) for each rotation of the antenna coil (130).

The rotating speed of antenna coil (130) is of several Hz˜several thousand Hz, such that the first harmonics power source of several hundred KHz˜several MHz may be pulsed as many as 4*(several˜several thousand) Hz. The rotating speed of antenna coil (130) can be adjusted to vary the on/off frequency optimized for removal strength of particles. This is because the number of insulation section between the first terminal (421) and the second terminal (412) is a mechanically predetermined constant.

Referring to FIGS. 1 to 8, the on/off frequency can be generated by mechanically and intermittently contacting the first and second terminals (421, 412) by providing the first terminal (421) on the first member including the antenna coil (130), and providing the second terminal (412) on the second member (400) including the power source unit (170).

In contrast to the comparative exemplary embodiment that pulses waveform by generating and overlapping the waveform using a generator in terms of circuitry, the present disclosure teaches the generation of second harmonics power source which pulses the first harmonics power source by mechanical and intermittent contact.

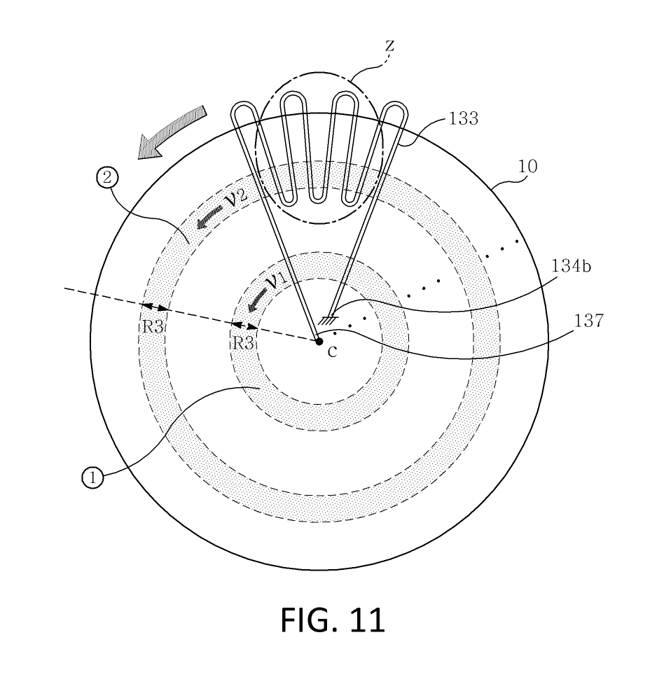

The mechanical and intermittent contact by the first and second terminals (421, 412) is made on the (+) side of the antenna coil (130) connected to the power source unit (170) applied with the first harmonics power source in the exemplary embodiments illustrated in FIGS. 1 to 8. However, the present disclosure is not limited to the exemplary embodiments of FIGS. 1 to 8 in which a (+) power switching unit is realized by forming a mechanical intermittent contact on the (+) power source side of the antenna coil (130), a ground portion switching unit may be realized that generates a mechanical intermittent contact with a ground portion grounded by the antenna coil (130) as shown in FIG. 9.

FIG. 9 illustrates a frame (340), which is a basic body for the plasma device according to the present disclosure, a frame ground terminal (340a) provided on the frame (340) and an antenna coil ground terminal (340b) configured to ground the antenna coil (130).

When an intermittent mechanical contact is generated between the frame ground terminal (340a) grounded to the frame (340) and the antenna coil ground terminal (340b) configured to ground the antenna coil (130), an intermittent mechanical contact may be generated as many as on/off frequency in which the rotating speed of the antenna coil (130) is multiplied by the number of insulation sections.

When the antenna coil (130) is rotated, the antenna coil (130) may be applied with a second harmonics power source that has pulsed a first harmonics power source as many as the on/off frequency by the intermittent mechanical contact between the frame ground terminal (340a) and the antenna coil ground terminal (340b).

That is, when the intermittent mechanical contact between the frame ground terminal (340a) and the antenna coil ground terminal (340b) is generated as many as the on/off frequency by connecting the first harmonics power source of the second member (400) connected by the power source unit (170) to the first terminal (421) of the antenna coil (130) through the second terminal (412) and by partially interposing an insulator between the frame ground terminal (340a) and the antenna coil ground terminal (340b), the antenna coil (130) may be applied with the second harmonics power source that has pulsed the first harmonics power source as many as the on/off frequency.

At least one of the first terminal (421), the second terminal (412), the frame ground terminal (340a) and the antenna coil ground terminal (340b) may be at least one of an elastically contacting metal brush of metal material, a conductive liquid a mercury a slip module and a conductive bearing, in order to allow an electric contact to be realized in a relatively rotating state.

It should be noted according to the present disclosure that various exemplary embodiments are possible in which only the (+) power switching unit of FIGS. 1 to 8 is employed, only the ground switching unit of FIG. 9 is employed, and the (+) power switching unit and ground switching unit are all employed, albeit not being illustrated.

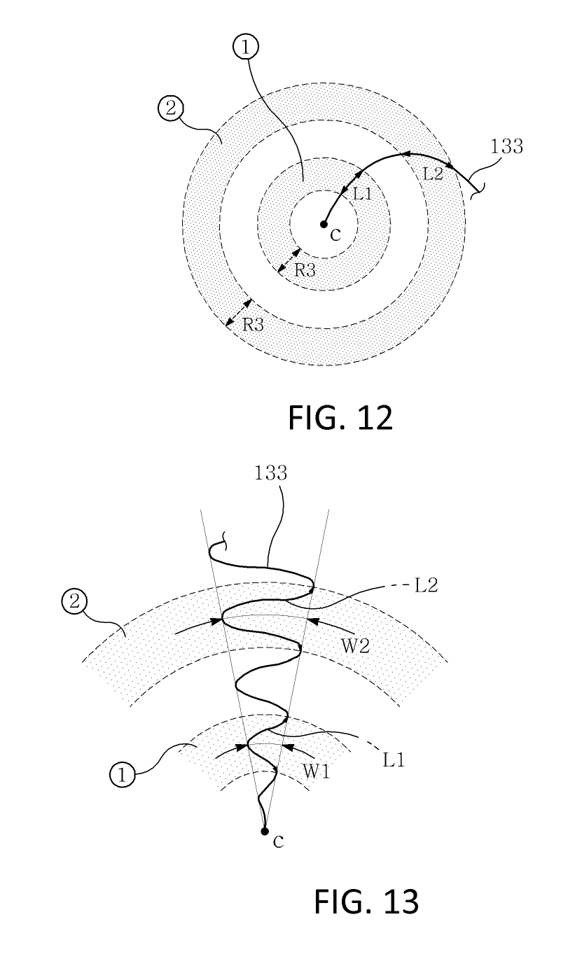

Now, the ground switching unit by ground portion of the antenna coil (130) will be described with reference to FIGS. 9 and 10.

Cooling water may flow into the antenna coil (130), a rear end (134b) of the antenna coil (130), a rotator (342) and the frame (340) through a cooling water hole (134c) provided at the rear end (134b) of the antenna coil (130). A rotating portion of a cooling water flowing passage may be tightly sealed by an O-ring (113).

The rear end (134b) of the antenna coil (130) may be fixed to the rotator (342) through a fastening hole (134d). The antenna coil (130) and the rotator (342) may rotate together by being fixed by the fastening hole (134d). The rotator (342) may be rotatatively supported relative to the antenna coil (130) and the frame (340). A bearing (350) may be interposed between the rotator (342) and the frame (340). When the bearing (350) is configured with a conductive metal, the bearing (350) may be the frame ground terminal (340a) and the antenna coil ground terminal (340b).

The ground switching unit may be realized when an insulator is inserted in one of between the frame (340) present with a relatively rotating circumferential surface and the bearing (350), into the bearing (350) and between the bearing (350) and the rotator (342), and an insulation section and a conduction section are alternately faced.

That is, as explained in FIG. 9, the ground switching unit may be realized when the insulation section and the conduction section are alternately faced on a portion where the rotation of the antenna coil (130) is supported relative to the frame (340).

Meantime, as illustrated in FIGS. 1 to 8, the (+) power source switching unit may be realized when insulation section and the conduction section are alternately faced between the power source unit (170) configured to generate the first harmonics power source and the antenna coil (130) or the chuck unit (150).

The antenna coil (130) illustrated in FIG. 10 may rotate on an imaginary line c-c′ as a rotation shaft.

The antenna coil (130) may include a central coil (131) which is a rotating center and a plurality of branch coils (133) connected in parallel to the central coil (131). A front end (137) connected to the central coil (131) and the rear end (134b) connected to the power ground unit of the branch coils (133) may be positioned on a substantially rotating coaxial. To this end, each of the branch coils (133) may take a ‘U’-shaped or a ‘C’-shaped one side-opened closed curve line look. A distal end of the central coil (131) may be electrically connected by a power source unit (170) configured to provide a harmonics power source through a slip ring (139).

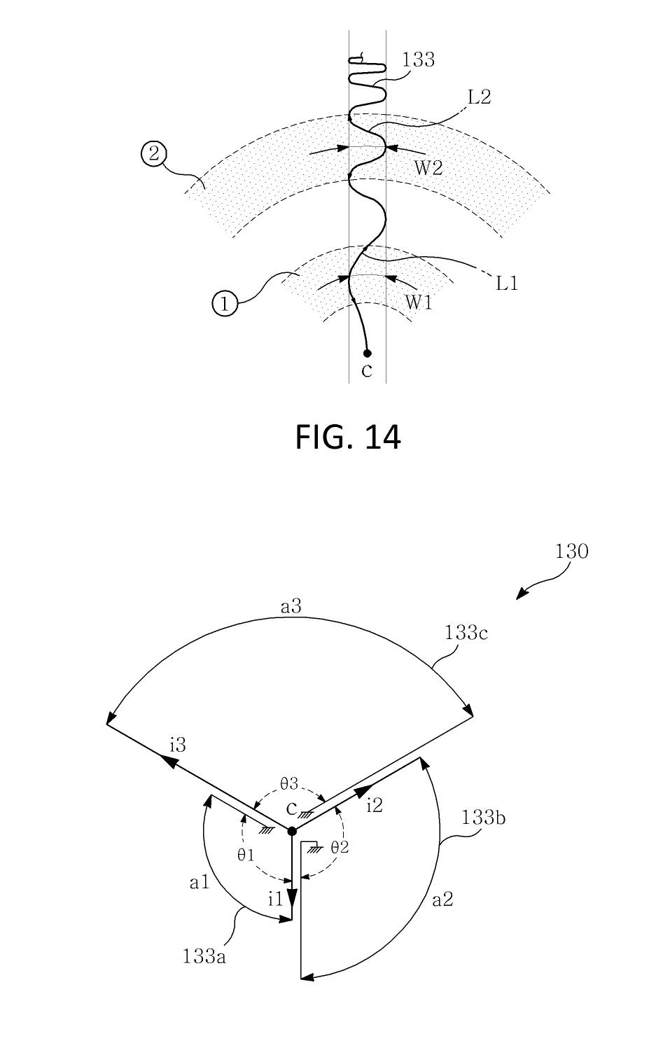

FIG. 11 is a perspective view illustrating an antenna coil (130) according to another exemplary embodiment of the present disclosure, where an circular arc portion is bent in a zigzag shape, and the branch coils (133) are schematically illustrated in bold lines.

When the antenna coil (130) is rotated, the intensity of plasma at a portion near to the rotation shaft c may be greater than that of a portion far from the rotation shaft c. The antenna coil (130) may be extended from the rotation shaft to a direction facing a circumference in order to cover an entire processed article (10).

For convenience of explanation, a first section \textcircled{1} and a second section \textcircled{2} of radially same length R3 are defined as below when seen from a plane view. The first section \textcircled{1} may be a section nearer to the rotation shaft over the second section \textcircled{2}. Furthermore, the first section \textcircled{1} and the second section \textcircled{2} may be formed within the scope of the processed article (10) when seen from a plane view.

The antenna coil (130), to be more specific, the branch coils (133) may rotate at a same angular velocity on the first section \textcircled{1} and the second section \textcircled{2}.

However, a linear velocity v1 of the branch coil (133) at the first section \textcircled{1} and a linear velocity v2 of the branch coil (133) at the second section \textcircled{2} may differ. To be more specific, v2 is greater than v1. This is because the linear velocity increases as being distanced from the rotation shaft. As a result, the linear velocity of antenna passing a particular point of the first section \textcircled{1} may be slower than that of antenna passing a particular point of the second section \textcircled{2}. Thus, an amount of plasma per unit time that is received by a particular point of the first section \textcircled{1} is greater than that of the second section \textcircled{2}. In other words, the intensity of plasma applied to the first section \textcircled{1} is greater than that of the second section \textcircled{2}.

According to the imbalance of plasma intensity thus discussed, the plasma process may be greatly performed near the center of the processed article (10), and the plasma process may be less performed near an edge. In order for the plasma process to be evenly performed across the entire area of the processed article (10), there is a need of the plasma intensity being uniform across the entire area of the processed article (10).

Hereinafter, a method of making the plasma intensity uniform will be discussed.

The antenna coil (130) may include a linear coil. The antenna coil (130) at this time may be formed in a fan-like shape. At this time, an circular arc portion \textcircled{z} of the antenna coil (130) may be bent in a zigzag shape. Furthermore, the zigzagged bent circular arc portion \textcircled{z} may be arranged on the second section \textcircled{2} of the processed article (10) when seen from a plane view. As a result, a length of a first portion passing the first section \textcircled{1} in the antenna coil (130) may be shorter than that of second portion passing the second section \textcircled{2}. According to this configuration, the intensity of plasma applied to the second section \textcircled{2} when the antenna coil (130) is in a stationary state is greater than that of the first section \textcircled{1}. However, the intensity of plasma applied to the first section \textcircled{1} and the second section \textcircled{2} may become almost same because of difference between linear velocity v1 and v2 in response to rotation.

In addition to the configuration of forming the circular arc portion \textcircled{z} in a zigzagged shape, various other methods including making a length L2 at the second portion longer than a length L1 of the first portion may be also employed.

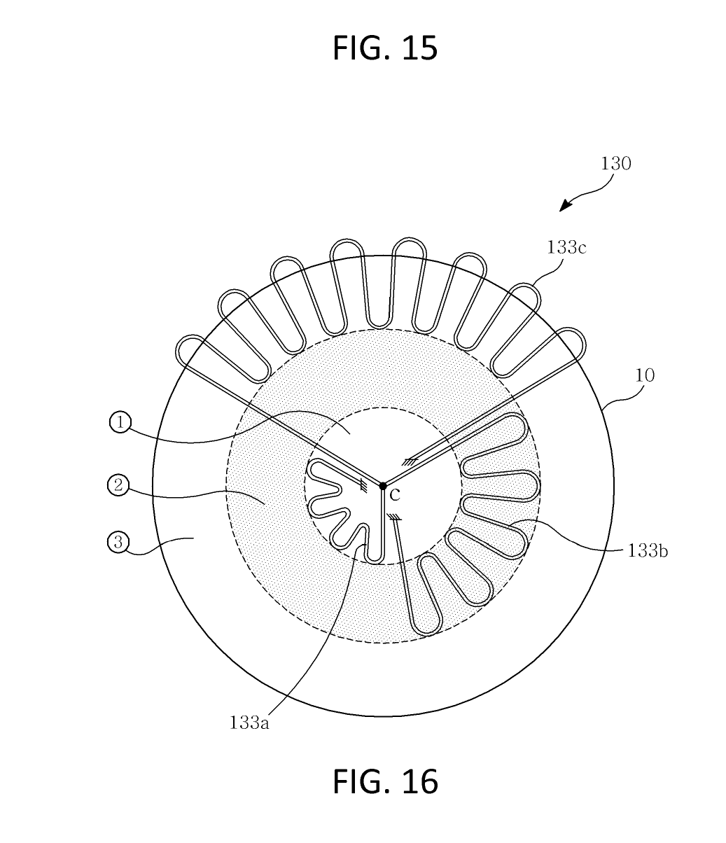

FIG. 12 is a schematic view illustrating an antenna coil (130) according to another exemplary embodiment of the present disclosure. The antenna coil (130) illustrated in FIG. 12 may be extended in a curved line shape from a rotation shaft to a periphery. According to this configuration, a length L2 at the second portion passing the second section \textcircled{2} may be made longer than a length L1 of the first portion passing the first section \textcircled{1}.

FIGS. 13 and 14 are schematic views illustrating an antenna coil (130) according to still another exemplary embodiment of the present disclosure.

The antenna coil (130) may be extended while taking a zigzagged bent shape from a rotation shaft to a periphery. For example, when the antenna coil (130) is formed in a fan-like shape, a relevant zigzag shape may be formed on a radius portion. For convenience of explanation, the antenna coil (130) will be explained by introducing an amplitude and period concept to the zigzag shape.

In order to make a line length L2 at the second portion passing the second section \textcircled{2} longer than a line length L1 of the first portion passing the first section \textcircled{1}, the amplitude and period of the antenna coil (130) may be changed. FIG. 13 illustrates an antenna coil (130) changed in amplitude according to an exemplary embodiment of the present disclosure, FIG. 14 illustrates an antenna coil (130) changed in period according to an exemplary embodiment of the present disclosure.

Referring to FIG. 13 first, the first portion passing the first section \textcircled{1} may be bent within a scope of first width w1. The second portion passing the second section \textcircled{2} may be bent within a scope of second width w2. For example, the antenna coil (130) may be bent in a zigzagged shape and extended from a rotation shaft to a direction facing the periphery.

The first width w1 may be greater than the thickness of the antenna coil (130). When the w1 and the thickness of the antenna coil (130) are same, the first portion may take a straight line shape. When the w1 is greater than the thickness of the antenna coil (130), the antenna coil (130) may take a bent zigzagged shape. At this time, the amplitude of the antenna coil (130) passing the first section \textcircled{1} may be restricted to within w1.

The second width w2 may be greater than the first width w1. At this time, the amplitude of antenna coil (130) passing the second section \textcircled{2} may be restricted to within w2. According to this configuration, the line length of the second portion L2 may be longer than a line length L1 of the first portion when zigzag-shaped periods are same, whereby intensity of plasma applied to the second section \textcircled{2} may be made greater than that of the first section \textcircled{1}. When a phenomenon is merged in which intensity of plasma applied to the first section \textcircled{1} is greater than that of the second section \textcircled{2} due to difference between the linear velocity v1 and v2, the intensity of plasma at the first section \textcircled{1} and that of the second section \textcircled{2} may be almost same.

Because the linear velocity gradually increases toward a peripheral direction, it is preferable that the width of antenna coil (130) gradually increase from the rotation shaft toward the periphery.

Referring to FIG. 14, the first portion passing the first section \textcircled{1} may be bent in a zigzagged shape having a first period. For example, the first portion may include a shape of a periodic function graph such as a sine wave or a square wave. The second portion passing the second section \textcircled{2} may take a shape of periodic function graph having a second period. At this time, the first period may be longer than the second period.

When amplitudes of each portion are same, and when the first period is longer than the second period, the line length L1 of the first portion may be shorter than the line length L2 of the second portion. Thus, an environment can be provided where the intensity of plasma increases from a center toward a direction facing the periphery. At this time, when a phenomenon is merged in which intensity of plasma applied to the first section \textcircled{1} is greater than that of the second section \textcircled{2} due to difference between the linear velocity v1 and v2, the intensity of plasma at the first section \textcircled{1} and that of the second section \textcircled{2} may be almost same.

The antenna coil (130) illustrated in FIG. 15 may be provided with a plurality of branch coils (133), each branch coil having a different rotating radius. According to this configuration, the intensity of plasma applied to the first section \textcircled{1} and that of the second section \textcircled{2} may be differently adjusted.

A first branch coil (133a) having a first rotating radius, a second branch coil (133b) having a second rotating radius and a third branch coil (133c) having a third rotating radius may be provided. The first rotating radius may be smaller than the second rotating radius. Furthermore, the second rotating radius may be smaller than the third rotating radius. The first branch coil (133a) may pass the first section. The second branch coil (133b) may pass the first section \textcircled{1} and the second section \textcircled{2}.

According to this configuration, two branch coils (133) may pass the first section \textcircled{1} and one branch coil (133) may pass the second section \textcircled{2}. Therefore, the intensity of plasma applied to the first section \textcircled{1} may be greater than that of the second section \textcircled{2}. According to this configuration, a configuration adequate to a plasma process in which the plasma intensity is strong near the rotation shaft and the plasma intensity is weak near the periphery may be provided. As discussed in the foregoing, if even plasma application to an entire of the processed article (10) is desired, several other configurations may be added.

A current i1 inputted to the first branch coil (133a) may be smaller than a current i2 inputted to the second branch coil (133b). According to this configuration, intensity of plasma generated by the first branch coil (133a) may be smaller than that generated by the second branch coil (133b).

Each of the first branch coil (133a) and the second branch coil (133b) may take a fan-like shape. When a sector angle θ1 of the first branch coil (133a) is smaller than a sector angle θ2 of the second branch coil (133b), a circular arc length a1 of the first branch coil (133a) may be shorter than a circular arc length a2 of the second branch coil (133b). Thus, the plasma intensity may be evenly spread when an circular arc portion of each branch coil (133) is made to pass the first section \textcircled{1} and the second section \textcircled{2}.

To be more specific, the first section \textcircled{1} in FIG. 15 may be positioned with a radius portion of the first branch coil (133a), a circular arc portion al and a partial radius portion of the second branch coil (133b). Furthermore, the second section \textcircled{2} may be positioned with the balance radius portion of the second branch coil (133b) and the circular arc portion a2.

At this time, a coil length positioned at the second section \textcircled{2} may be greater than a coil length positioned at the first section \textcircled{1} due to length difference between al and a2. Furthermore, when the circular arc portion of each branch coil (133) is bent in a zigzag shape, this phenomenon will be more significantly shown. Furthermore, the intensity of plasma generated by the second section \textcircled{2} may be greater because a2 flows a current i2 which is greater than il. Each input terminal of branch coils (133) may be different in order to apply a current of different intensity to each branch coil (133).

As illustrated in FIG. 10, the first branch coil (133a) and the second branch coil (133b) may take a configuration of being connected to a same input terminal. In this case, a resistance of the first branch coil (133a) may be greater than that of the second branch coil (133b) in order to differentiate a current applied to the first branch coil (133a) and the second branch coil (133b). At this time, when a same voltage is inputted to the input terminal, a larger amount of current i2 flows to the second branch coil (133b) having a low resistance, and a small amount of current il may flow to the first branch coil (133a) having a high resistance.

Materials may be made different in order to differentiate the resistances of first branch coil (133a) and the second branch coil (133b), and a cross-sectional area of each branch coil (133) may be made to be different. For example, resistance decreases as a cross-sectional area of conductor increases, such that the above conditions may be met if the first branch coil (133a) is made thinner than the second branch coil (133b).

The circular arc portions of the first branch coil (133a), the second branch coil (133b) and the third branch coil (133c) of the antenna coil (130) illustrated in FIG. 16 are all bent in a zigzag shape. The first branch coil (133a) may be formed to cover the size of the first section \textcircled{1}, and the second branch coil (133b) may be formed to cover the size of the second section \textcircled{2}. Furthermore, the third branch coil (133c) may be formed to cover the size of the third section \textcircled{3}.

To be more specific, the amplitude of circular arc portion bent in the zigzagged shape of the first branch coil (133a) may be less than a length of the first section \textcircled{1}, because it is difficult to extend the circular arc portion to the rotation shaft. The amplitude of circular arc portion bent in the zigzagged shape of the second branch coil (133b) may be same as a length of the second section \textcircled{2}. The amplitude of circular arc portion bent in the zigzagged shape of the third branch coil (133c) may be greater than a length of the third section \textcircled{3}, because this is to evenly plasma-process the peripheral portion of the processed article (10).

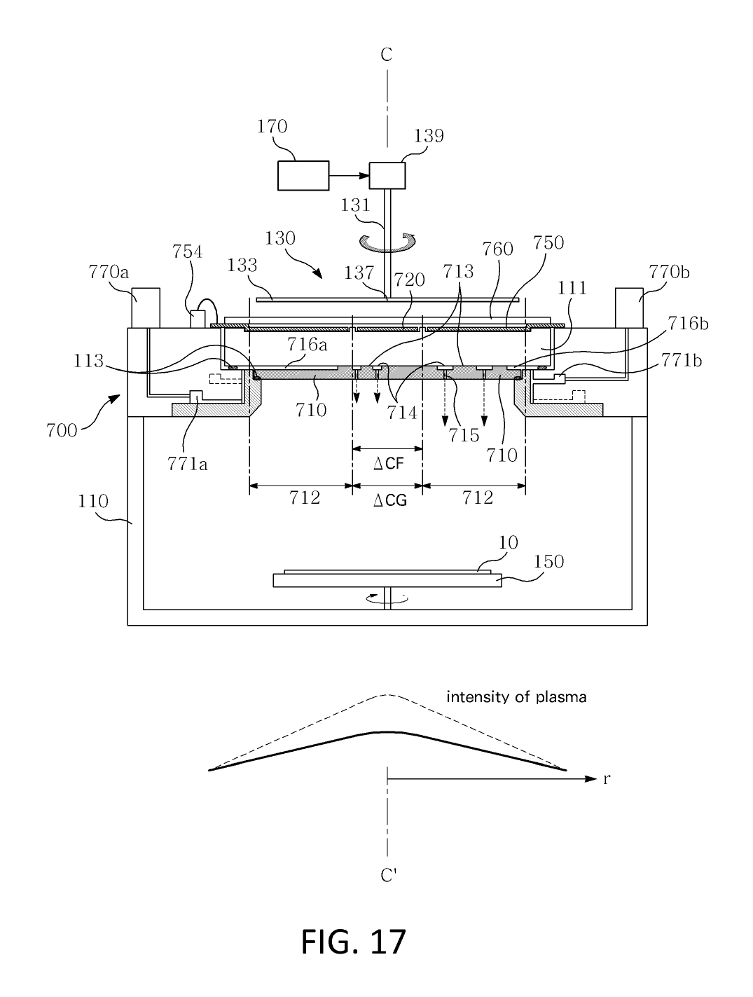

FIG. 17 is a schematic cross-sectional view illustrating a plasma device according to still another exemplary embodiment of the present disclosure.

Referring to FIG. 17, the plasma device may include a chamber (110) and a rotating antenna coil (130). The chamber (110) may be provided with a chuck unit (150). The chuck unit (150) may be provided with a wafer and a substrate as plasma-processed processed articles (10). Reaction gas such as argon gas adequate for activating the plasma may be provided into the chamber (110) through a gas plate (710). The reaction gas introduced into the chamber (110) may be excited in a plasma state by the electromagnetic field generated by the antenna coil (130).

The antenna coil (130) may be installed outside of the chamber (110) according to the ICP method and may be installed inside the chamber (110) according to the CCP method (not shown). The antenna coil (130) may be applied with a harmonics RF power source in order to generate the electromagnetic field.

The antenna coil (130) may be provided at an upper surface of the chamber (110). A cover (111) configured to tightly seal the upper surface of the chamber (110) may be positioned at an accommodation space between the antenna coil (130) and the chamber (110), and an O-ring may be provided to maintain the vacuum state, and the cover (111) may be a quartz glass plate configured to project the electromagnetic field into the chamber (110), a ceramic RF window or a dielectric plate.

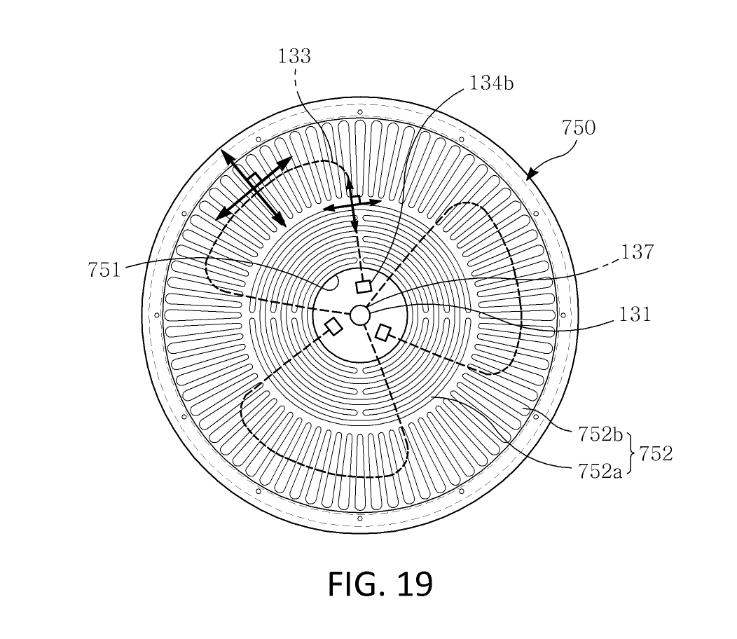

Referring to FIG. 19, the antenna coil (130) may include a central coil (131) which is a rotating center, and a plurality of branch coils (133) each connected in parallel to the central coil (131). The branch coil (133) may include a front end (137) connected to the central coil (131) and the rear end (134b) connected to the power ground unit, and the front end (137) and the rear end (134b) of the branch coils (133) may be positioned on a substantially rotating coaxial. To this end, each of the branch coils (133) may take a ‘U’-shaped or a′C′-shaped one side-opened closed curve line look.

In the exemplary embodiment, a Faraday shield plate (750) or an eddy current plate (720) may be provided to further increase the uniformity of plasma instead of shape optimization of the fixed antenna coil (130) or rotation of the antenna coil (130).

Referring to FIG. 19, the antenna coil (130) is positioned at a central area with a central coil (131) applied with a power source and a read end (134b) grounded by each branch coil (133). When a voltage applied to the central coil (131) or applied to the front end (137) of each branch coil (133) connected in parallel to the central coil (131) is defined as V, an average voltage of a central area of the antenna coil (130) may be also defined as V, because the front end (137) and the rear end (134b) of each branch coils (133) are adjacent.

The antenna coil (130) may be positioned at a periphery with a central portion of each branch coil (133). The branch coil (133) acts as a resistance proportionate to the length from the front end (137) toward the read end (134b), and the branch coil (133) may take a shape of returning back to the central area from the center through the periphery. Thus, each branch coil (133) may have a predetermined average voltage V across the center to the periphery. The average voltage may be constant from the center to the periphery in consideration of only the radius direction of the antenna coil (130) as a first dimension coordinate axis.

However, in view of a cylindrical coordinate system using a radius direction of the antenna coil as one-dimension coordinate axis, and a peripheral direction as a two-dimension coordinate axis, an average voltage for each unit area may decrease toward a peripheral portion where the branch coil (133) is fully unfolded. Thus, the rotation of antenna coil (130) may be the major characteristics of the present disclosure in order to alleviate a difference of average voltage for each unit area and to evenly match the intensity of electromagnetic field at the peripheral portion.

Despite equalization by symmetrical shape (‘U’ shape) of the antenna coil (130) and equalization by rotation, the average voltage, the electromagnetic field and plasma intensity at a central portion of the antenna coil (130) may be higher than those at the periphery. In order to alleviate this imbalance, the Faraday shield plate (750) or an eddy current plate (720) may be provided.

In one exemplary embodiment, the eddy current plate (720) may be arranged at a center of the Faraday shield plate (75) facing the antenna coil (130). The eddy current plate (720) may be preferably a ferromagnetic substance or a paramagnetic substance. When an RF power source is applied to the antenna coil (130), an eddy current is induced on the eddy current plate (720) as harmonics, whereby the eddy current plate (720) is heated. The heating of the eddy current plate (720) corresponds to an energy loss at a center portion of the antenna coil (130) to thereby shield the electromagnetic field of the antenna coil (130) in view of correspondence to the heating. The eddy current plate (720) may not be grounded for induction heating.

The electromagnetic field generated from the center of the antenna coil (130) is consumed for heating of the eddy current plate (720), whereby the intensity of plasma induced into the chamber (110) may decrease at the center portion. When the heat of the heated eddy current plate (720) is transmitted to a center of dielectric cover (111), a center portion of the cover (111) is heated, and sputtering, etching or polymer absorption may be restricted by temperature rise of the cover (111). When the eddy current plate (720) or the dielectric cover (111) is heated by the eddy current induced to the ferromagnetic substance or the paramagnetic substance, a temperature by which the polymer is formed on a surface of the dielectric cover (111) facing an inner surface of the chamber (110) can be controlled, and sputtering or etching of the cover (111) can be restricted.

At least one of a rotation shaft portion of the antenna coil (130), a portion crossed by the central coil (131) and the branch coil (133), the front end (137) of the branch coil (133) and the rear end (134b) of the branch coil (133) may be positioned at a center portion of the antenna coil (130), and the center portion of the antenna coil (130) may be shielded by the eddy current plate (720).

The center portion of the antenna coil (130) is difficult to specify a current direction, such that it may be difficult to constantly control a pass characteristic of the electromagnetic field by the Faraday shield plate (750) with a slot opened to a predetermined direction. The slot (752) processing is difficult to be performed at the very center of the Faraday shield plate (750). Thus, a central hole (751) may be opened at a center of the Faraday shield plate (750) facing a central portion of the antenna coil (130), and the central hole (751) may be arranged with the eddy current plate (720).

The center of the Faraday shield plate (750) may be inserted by the eddy current plate (720) made of ungrounded ferromagnetic substance or paramagnetic substance to thereby shield the electrostatic wave projected into the chamber (110). If necessary, an edge area of the dielectric cover (111), not limiting the central area of the dielectric cover (111), may be also inserted by the eddy current plate (720) made of ferromagnetic substance or paramagnetic substance to adjust the uniformity of the plasma and to control temperatures of a wide area of RF window.

A dotted line graph at the bottom area of FIG. 17 shows the intensity of plasma inside the chamber (110) when the eddy current plate (720) or the Faraday shield plate (750) is not provided, and the solid line graph at the bottom area of FIG. 17 illustrates the intensity of plasma provided with the eddy current plate (720) and the Faraday shield plate (750) according to the present disclosure.

With reference to FIG. 17, the intensity of plasma decreases due to the eddy current plate (720) at the central area of the antenna coil (130) to thereby equalize the intensity of plasma. Furthermore, the intensity of plasma can be equalized by the Faraday shield plate (750) at an area excluding the central area of the antenna coil (130).

The Faraday shield plate (750) will be explained hereinafter.

When an electric potential of plasma inside the chamber (110) is oscillated or an electric potential of antenna coil (130) is greatly changed, a self bias, in which voltage imbalance to circuit itself of the antenna coil (130) is generated, may occur. When the potential of plasma is vibrated or the magnitude of RF power source applied to the antenna coil (130) is greatly changed during the process, the dielectric cover (111) contacting the plasma or inside of the chamber (110) may be eroded by sputtering or etching. When the potential of the dielectric cover (111) decreases during generation of self bias or E mode operation of the ICP plasma device, the effect of ions inside the plasma sputtering or etching the dielectric cover (111) may be increased.

The Faraday shield plate (750) may restrict generation of plasma caused by E mode or may reduce the size of self bias. The Faraday shield plate (750) may be interposed between the antenna coil (130) and the dielectric cover (111) to shield only the electromagnetic field between the antenna coil (130) and the dielectric cover (111) and project only the electromagnetic field to the dielectric cover (111) and the chamber (110).

The principle of Faraday shield plate (750) may be just like the principle of decreasing the intensity of electric field formed between two electrodes by inserting a conductive plate such as copper, instead of inserting a dielectric substance between the capacitor electrodes. However, when the Faraday shield plate (750) completely shield the antenna coil (130), not only the electric field formed by the antenna coil (130) but also the magnetic field are also completely shielded, such that it is impossible to generate plasma (H mode) using formation of induced electric field within the chamber (110) or using the magnetic field. Thus, it is necessary to adjust a shield area or a shield shape of the Faraday shield plate (750).

To this end, a slot (752) extended to a direction perpendicular to an extension direction of the antenna coil (130) or to a direction perpendicular to a current direction of the antenna coil (130) may be formed on the Faraday shield plate (750). The slot (752) may be opened to a direction perpendicular to the extension direction of the antenna coil (130) or to a direction perpendicular to the current direction of the antenna coil (130). The slot (752) may pass the electromagnetic field generated to a direction perpendicular to the current direction of the antenna coil (130) to thereby guide the dielectric cover (111). A metal plate portion excluding the slot (752) on the Faraday shield plate (750) may shield only the electric field but pass only the electromagnetic field and guide the electromagnetic field to the dielectric cover (111).

As the processed article (10) grows larger, the chamber (110) may also grow larger to make the temperature of the dielectric cover (111) corresponding to the RF window become non-uniform. This is because of an effect of ions inside the plasma sputtering or etching the dielectric cover (111). Thus, the temperature uniformity of the dielectric cover (111) can be controlled by adequately adjusting the shape of the slot at the Faraday shield plate (750) and grounding the Faraday shield plate (750).

In one exemplary embodiment, the Faraday shield plate (750) may include an opened slot extended to a direction perpendicular to the antenna coil (130). Slots (752) of at least two patterns may be formed to form a customized slot (752) corresponding to the shape of the rotating antenna coil (130).

The Faraday shield plate (750) may be a thin conductive metal plate such as copper, and grounded to a ground unit (754). The Faraday shield plate (750) formed with a plurality of shaped slots may be interposed between the antenna coil (130) and the dielectric cover (111) to realize the plasma uniformity.

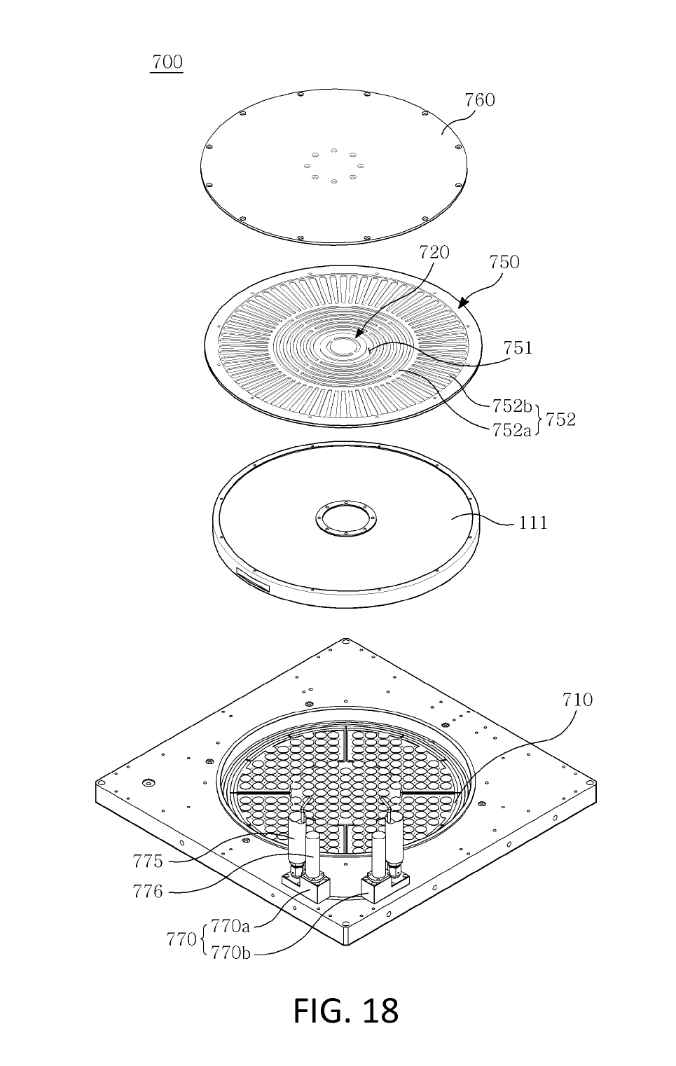

Referring to FIG. 18, the slot (752) may include a first slot (752a) facing a central area of the antenna coil (130), and a second slot (752b) facing a peripheral area of the antenna coil (130). The branch coil (133) is extended to a radial direction at an inner circumferential portion of the antenna coil (130) and the first slot (752a) may be extended to a circumferential direction of the Faraday shield plate (750). The branch coil (133) at the peripheral portion of the antenna coil (130) may be extended to a circumferential direction, such that the second slot (752b) may be extended to a radial direction of the Faraday shield plate (750).

The extended direction of the branch coil (133), or the current direction is mutually perpendicular at an inner circumferential portion and an outer circumferential portion of the antenna coil (130), whereby the first and second slots (752a, 752b) may be perpendicular at the extension directions.

The first slot (752a) may face the front end (137) and the rear end (134b) of the branch coil (133) facing a radial direction of the antenna coil (130), and the second slot (752b) may face a mid section of the branch coil (133) facing the circumferential direction of the antenna coil (130), and the first and second slots (752a, 752b) may be perpendicular to the extended direction of the branch coil (133).

The conventional fixed antenna has a tendency of fast diffused degree due to high electron temperature as the frequency becomes low to thereby better the uniformity. However, the conventional fixed antenna suffers from a disadvantage of requiring a broadly spaced chamber (110) in order to overcome a potential difference which is a structural problem inherent in the conventional fixed antenna.

Meantime, when the Faraday shield plate (750) is installed in the conventional antenna, the obtainment of uniformity in plasma is restricted regardless of how hard the slot (752) shape of the Faraday shield plate (750) is optimized. This is because there is a limit in designing the slot (752) to make the antenna and the slot (752) perpendicular at all sections, and as the antenna is fixed, it is impossible to accomplish the dynamic equalization, and as the antenna and the slot (752) are fixed, only a static equalization can be accomplished that depends on the slot (752) shape.

In contrast, the present disclosure is configured in a manner such that the antenna coil (130) rotates or linearly moves to achieve the dynamic movement, and the Faraday shield plate (750) is in a stationary state, or albeit not shown, the antenna coil (130) is fixed and the Faraday shield plate (750) rotates or linearly moves to accomplish the dynamic movement.

According to the present disclosure where the Faraday shield plate (750) formed with the slot (752) and the antenna coil (130) relatively move, the limitation of the extended direction of the slot (752) and the antenna coil (130) being perpendicular can be alleviated, and most of all, the dynamic equalization can be advantageously accomplished.

An RF window unit (700) will be explained hereinafter.

The RF window unit (700) may support the dielectric cover (111) and tightly seal an upper surface of the chamber (110). The RF window unit (700) may include at least one of a cover plate (760) formed with dielectric substance, a Faraday shield plate (750) formed with a metal material, an eddy current plate (720) formed with a ferromagnetic substance or a paramagnetic substance, and a gas plate (710). The RF window unit (700) may be formed with an aluminum material. The RF window unit (700) may be formed therein with a gas supply path. The gas supply path may be a plurality of independently formed paths connected to the gas plate. The gas may be differentially supplied to each path in response to intensity of plasma inside the chamber (110).

The RF window unit (700) may cover an upper side of the chamber (110), and may be a structure assembled by individual parts using a coupling member, or a structure bonded by adhesive.

Although the Faraday shield plate (750) and the eddy current plate (720) are formed with a thin metal plate, there is a need that the Faraday shield plate (750) and the eddy current plate (720) are so installed as not to be exposed to the outside. When the RF window unit (700) is installed with the Faraday shield plate (750) and the eddy current plate (720) in an integral manner or an assembled manner, the material that wraps the Faraday shield plate (750) or the eddy current plate (720) may be used with the same dielectric substance as that of the dielectric cover (111) in order to pass the electromagnetic field.

At this time, a coupling effect between the antenna coil (130) and the plasma in response to dielectric constant of the dielectric substance, as thickness of the dielectric substance that wraps the Faraday shield plate (750) or the eddy current plate (720) increases, or an electric efficiency may deteriorate that generates plasma by high current flowing in the antenna coil (130).

In an exemplary embodiment, the cover plate (760) may be a thin plate formed with dielectric substance. The cover plate (760) may be arranged at a space formed by the Faraday shield plate (750) or the eddy current plate (720) and rotating antenna coil (130), and a space configured to maximally exercise the plasma efficiency may be formed at a bottom surface of the antenna coil (130).

Meantime, a gas plate (710) configured to supply reaction gas into the chamber (110) may be arranged between the dielectric cover (111) and the chamber (110), and uniform plasma may be formed inside the chamber (110) by differing the gas ejection characteristics for each area of the gas plate (710). The gas plate (710) according to the present disclosure is formed with a plurality of supply paths of reaction gas in order to adjust the ejection amount of reaction gas in response to intensity of plasm for each area, where each gas supply path may be independently formed.

The gas ejection amount for each area is independently controlled to be inversely proportionate to plasma intensity for each area, whereby uniform deposition or etching can be performed on the processed article (10). The gas plate (710) is divided into a plurality of independent divisional areas (718), and supply amount of reaction gas for each unit area may be differently controlled for a first area (711) including a central area of the gas plate (710) and a second area (712) including an edge area. For example, the gas ejection amount for each unit area may be greater in the second area (712) where plasma intensity is weak than the first area (711) where the plasma intensity is strong.

The gas plate (710) is protrusively formed with embossing patterns (713) and may be divided into a plurality of areas each having a gas ejection amount inversely proportionate to the plasma intensity along a radius direction. In addition, the gas plate (710) may be re-divided into a plurality of areas along a circumferential direction.

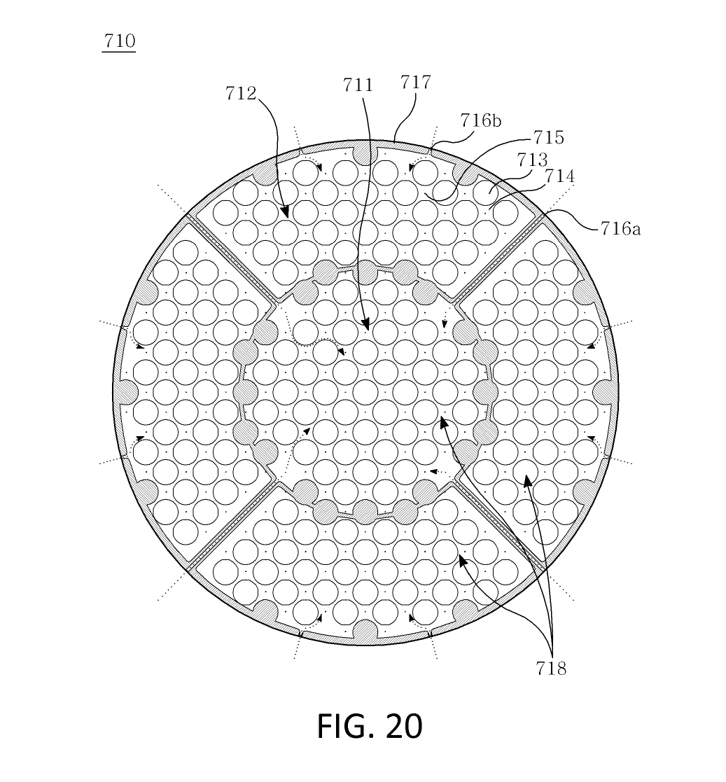

Referring to FIG. 20, each divided second area (712) may be provided with a plurality of second area gas supply holes (716b). Each divided second area (712) may be connected by two same number of second area gas supply holes (716b). The mutually different second area gas supply hole (716b) may be connected to a common valve, or to a common second supply gas path (771b), whereby each gas supply hole may receive gas of same pressure and same amount. The gas supply amount may be uniformly controlled to a broad area by increasing the number of second area gas supply holes (715b) and by connecting the same number of second area gas supply holes (716b) for each divided area.

The illustrated gas plate (710) may be divided into five (5) areas including one first area (711) and a second area (712) divided into four sections. Albeit not being illustrated, the gas supply to a circumferential direction may be differentially controlled by not commonly connecting the second area gas supply hole (716b) to the second supply path (771b), or by independently controlling the gas supply amount for each second area gas supply hole (716b).

Albeit not being illustrated, the gas plate (710) may be divided to three areas including a central area of gas plate (710) along a radius direction of the gas plate (710), a middle area of the gas plate (710) and an edge area of the gas plate (710), when a processed object or the chamber (110) is great, and the gas may be independently supplied for further subdivided areas.

In an exemplary embodiment, the gas plate (710) may be provided with a dam pattern (717) or an embossing pattern (713) formed by protruding a portion of the gas plate (710). The dam pattern (717) may be arranged at a border of each divisional area (718), which can isolate a gas path of a particular area from a gas path of other areas. The first area gas supply hole (716a) may be positioned between the dam pattern (717) and the dam pattern (717), and may become a path configured to supply the gas to a central area of the gas plate (710) surrounded by the dam patterns (717).

The embossing pattern (713) can tightly contact the gas plate (710) to the dielectric cover (111) by removing an empty space between the gas plate (710) and the dielectric cover (111). The embossing pattern (713) may come in various shapes such as square, triangle and comb structures, where it is preferable that a path configured to pass the gas be minimized or a partial pressure of the gas be maximized.

A gas channel (714) is a gas flowing path between the embossing pattern (713) and the embossing pattern (713). The gas channel (714) may be formed with a gas nozzle (715) to eject gas into the chamber (110). The gas channel (714) may have a height less than 1 mm.

The plasma efficiency may decrease inside the chamber (110) when discharge plasma is generated in the empty space between the gas plate (710) and the dielectric cover (111).

Discharge plasma restriction means can reduce a gap size between the gas plate (710) and the dielectric cover (111), can reduce a time in which the gas stays in the gas plate (710), can increase mobility of the gas, or can increase a partial pressure of the gas to a maximum pressure where the discharge plasma is not generated. The discharge plasma restriction means may be obtained by various types such as embossing pattern (713), the number of gas supply holes and arrangement structure and supply unit (770).

It is preferable that a protruding height of the embossing pattern (713) be less than 0.5 mm in order to prevent the discharge plasma from being generated in the empty space between the gas plate (710) and the dielectric cover (111). An object of the embossing pattern (713) is to minimize the size of gas path in order to restrict the discharge plasma.

In a comparative exemplary embodiment, when a gap is formed using a protruding pattern between the mutually contacting dielectric cover (111) and the gas plate (710) as in the present disclosure, instead of flowing the gas in a hole by forming the hole inside the gas plate (710), the fluidity or mobility of gas can be enhanced, the staying time of gas inside the gas plate (710) can be reduced and a partial pressure during gas flow can be increased.

The gas supply hole including the first area gas supply hole (716a) of the second area gas supply hole (716b) may be opened toward an outside of the gas plate (710). The gas supplied from outside may be supplied to each divisional area (718) through the gas supply hole, and may be differentially ejected for each radius or circumference through the gas nozzle (715) of each divisional area 9718).

Referring to FIGS. 17 and 18, a supply unit (770) may be provided to control the flow of gas supplied to the gas plate (710) from the outside. The supply unit (770) can restrict the generation of discharge plasma by allowing the gas supply to be realized at a shortest distance. The supply unit (770) may be provided in a plural number in order for the gas to be differentially ejected for each divisional area (718) of the gas plate (710), whereby each divisional area (718) can be independently connected.

In the illustrated exemplary embodiment, two supply units (770) are provided in order to differentially eject the gas to the first area (711) and to the second area (712) in response to the plasma intensity. In an exemplary embodiment not illustrated, mutually different supply units (770) are shown for each circumferential divisional area (718) of the second area (712).

In an exemplary embodiment, the supply unit (770) may include a first supply unit (770a) configured to supply the gas to a central area of the gas plate (710), and a second supply unit (770b) configured to supply the gas to an edge area of the gas plate (710).

The first supply unit (770a) is connected to a first supply path (771a) formed at the RF window unit (700), and the second supply unit (770b) is connected to the gas nozzle (715) of the second area (712) through the second area gas supply hole (716b) opened to the outside of the gas plate (710). In an exemplary embodiment, each supply unit (770) may include a proportional control valve (775) configured to control the gas amount, and a pressure measurer (776) configured to measure gas pressure. A measured value of the pressure measurer (776) may be returned to a proportional control valve (775), whereby the gas amount can be proportionally controlled.

The gas supplied to the RF window unit (700) through an outside on/off valve (not shown) may pass the supply unit (770). The gas introduced into the RF window unit (700) is divided to two pipe conduits and divided to a first supply unit (770a) and a second supply unit (770b). Each supply unit (770) may be formed with a proportional control valve (775) and a pressure measurer (776).

Four first area gas supply holes (716a) may be connected to the first area (711) which is a central area, and two second area gas supply holes (716a) may be allocated to each area that divides the second area which is an edge area. The gas may be supplied to four divided areas of the second area (712).

The uniformity of plasma on the processed article (10) can be adjusted when the gas supply amount is adjusted in response to the electromagnetic field transmitted to the chamber (110).

In the present disclosure, the gas supply line inside the RF window unit (700) installed at an upper surface of the chamber (110) is divided, and two pairs of proportional control valves (775) and pressure measurers (776) may be independently installed at a shortest distance.

Although the present disclosure has been described in detail with reference to the foregoing embodiments and advantages, many alternatives, modifications, and variations will be apparent to those skilled in the art within the metes and bounds of the claims. Therefore, it should be understood that the above-described embodiments are not limited by any of the details of the foregoing description, unless otherwise specified, but rather should be construed broadly within the scope as defined in the appended claims

What is claimed is:

1. A plasma device, the plasma device comprising:
a first member including a chuck unit accommodated with an antenna coil or a processed article so rotating as to generate a plasma inside a chamber; and
a second member connected with a first harmonics power source, wherein
the first member is provided with a terminal, and the second member is provided with a second terminal, and a second harmonics power source, which has pulsed the first harmonics power source in response to a relative rotation between the first and second terminals, is applied to the first member.

2. The plasma device of claim 1, wherein the first and second terminals are alternately provided with a mutually and electrically connected conduction section and a mutually and electrically cut-off insulation section.

3. The plasma device of claim 1, wherein the first terminal is arranged at a position tangent to an imaginary circumference, the second terminal rotates along the imaginary circumference, and a length of the first terminal is shorter than that of the imaginary circumference.

4. The plasma device of claim 1, wherein the first terminal is provided in a plural number and each first terminal is arranged by being spaced apart from the other first terminal.

5. The plasma device of claim 1, wherein an intermittent mechanical contact is generated between the first and second terminals in response to the relative rotation between the first and second terminals, and the second harmonics power source is applied to the first member, where the second harmonics power source intermittently turns on/off the first harmonics power source in response to the intermittent mechanical contact.

6. The plasma device of claim 1, wherein an intermittent mechanical contact is generated between a frame ground terminal grounded to a frame and an antenna coil ground terminal grounded to an antenna coil, and the first member is applied with the second harmonics power source that has pulsed the first harmonics power source as much as on/off frequency in response to the intermittent mechanical contact between the frame ground terminal and the antenna coil ground terminal.

7. The plasma device of claim 6, wherein at least one of the first terminal, the second terminal, the frame ground terminal and the antenna coil ground terminal is at least one of a metal brush elastically contacted by a metal material, a conduction liquid, a slip module and a conduction bearing.

8. The plasma device of claim 1, wherein the antenna coil is formed with a fan shape, and a circular arc portion of the antenna coil is bent in a zigzag shape, and the antenna coil rotates about a center of the circular arc as a rotation shaft.

9. The plasma device of claim 1, wherein the antenna coil is extended to a direction facing a periphery from the rotation shaft, a first section is a section near to the rotation shaft compared with the second section, when the first section and the second section of radially same length are defined, and a length of a first portion in the antenna coil passing through the first section is shorter than that of a second portion passing through the second section.

10. The plasma device of claim 1, wherein the antenna coil rotates about the rotation shaft, the antenna coil is bent in a zigzag shape and extended to a direction facing a periphery from the rotation shaft, and a width of the antenna coil is gradually increased toward the periphery from the rotations shaft.

11. The plasma device of claim 1, wherein the antenna coil rotates about the rotation shaft, and the antenna coil is provided with a plurality of branch coils, each branch coil having a different rotation radius.

12. The plasma device of claim 1, further comprising: a dielectric cover configured to tightly seal the chamber; and
a Faraday shield plate formed with a plate of metal material arranged between the dielectric cover and the antenna coil to be electrically grounded, wherein the antenna coil and the Faraday shield plate perform a relative movement when the plasma is generated.

13. The plasma device of claim 12, wherein the Faraday shield plate includes a slot extended to a direction perpendicular to an extension direction of the antenna coil or to a direction perpendicular to a current direction of the antenna coil, wherein the slot is opened to a direction perpendicular to the extension direction of the antenna coil or to a direction perpendicular to the current direction of the antenna coil.

14. The plasma device of claim 12, wherein the Faraday shield plate is formed with a slot, wherein the slot includes a first slot facing a central area of the antenna coil, and a second slot facing a peripheral area of the antenna coil, and wherein the first slot is extended along a circumferential direction of the Faraday shield plate, and the second slot is extended along a radial direction of the Faraday shield plate.

15. The plasma device of claim 12, further comprising an eddy current plate formed with a ferromagnetic substance or a paramagnetic substance and interposed between the antenna coil and the dielectric cover to be heated by the antenna coil or to heat the dielectric cover.

16. The plasma device of claim 15, wherein the eddy current plate is arranged at a central hole centrally formed at the Faraday shield plate and un-grounded when the Faraday shield plate is grounded.

17. The plasma device of claim 1, further comprising an RF window unit configured to support the dielectric cover and to tightly seal the chamber, wherein the RF window unit includes at least one of the Faraday shield plate, a cover plate formed with dielectric substance configured to cover the Faraday shield plate, an eddy current plate formed with a ferromagnetic substance or a paramagnetic substance, and a gas plate configured to eject gas into the chamber, and is formed therein with a gas supply path facing the gas plate.

18. The plasma device of claim 12, further comprising a gas plate configured to eject gas into the chamber, and the gas plate is protrusively formed with embossing patterns tightly attached to the dielectric cover, and a gas nozzle is arranged among the embossing patterns configured to eject the gas into the chamber.

19. The plasma device of claim 12, further comprising a gas plate, and when the gas plate is divided into a plurality of divisional areas, each divisional area is divided by a dam pattern configured to protrude a portion of the gas plate.

20. The plasma device of claim 12, further comprising restriction means configured to restrict generation of plasma in an empty space between the gas plate configured to supply the gas to the chamber and the dielectric cover, wherein the restriction means reduces a gap size between the gas plate and the dielectric cover, reduces a time in which the gas stays in the gas plate, increases mobility of the gas, or increases a partial pressure of the gas.
